(19) United States
(12) Patent Application Publication
(10) Pub. No.: US 2026/0082978 A1
(43) Pub. Date: Mar. 19, 2026

(54) METHOD FOR MANUFACTURING SEMICONDUCTOR DEVICE AND SEMICONDUCTOR DEVICE

(71) Applicant: Mitsubishi Electric Corporation, Tokyo (JP)

(72) Inventor: Daisuke MURATA, Tokyo (JP)

(73) Assignee: Mitsubishi Electric Corporation, Tokyo (JP)

(21) Appl. No.: 19/400,201

(22) Filed: Nov. 25, 2025

Related U.S. Application Data
(62) Division of application No. 18/146,283, filed on Dec. 23, 2022.

(30) Foreign Application Priority Data
Apr. 6, 2022 (JP) 2022-063201

(51) Int. Cl. H01L 21/56; C23C 18/12; H01L 23/00; H01L 23/29; H01L 23/31

(52) U.S. Cl. CPC H10W 74/01; C23C 18/122; H10W 74/111; H10W 74/40; H10W 72/01315; H10W 72/07331; H10W 72/07554; H10W 90/756

(57) ABSTRACT

A coating process of a coating liquid using a nozzle is performed on a coating target structure including a semiconductor element and a wire bonded to the semiconductor element by a wire bonding process. The nozzle has a transport wind generating function of generating a liquid transport wind in a spiral manner. Thus, the coating liquid discharged from the coating liquid supply port of the nozzle is supplied to the coating target structure along the directivity of the liquid transport wind. Then, a drying process is performed on the coating target structure to form a primary layer containing a silane coupling agent as a constituent material on an outer periphery of the wire.

### CROSS-REFERENCE TO RELATED APPLICATIONS

This application is a Divisional of U.S. patent application Ser. No. 18/146,283 filed Dec. 23, 2022, which claims benefit of priority to Japanese Patent Application No. 2022-063201 filed Apr. 6, 2022, the entire contents of which are incorporated herein by reference.

### BACKGROUND OF THE INVENTION

### Field of the Invention

The present disclosure relates to a method for manufacturing a semiconductor device, and more particularly to a method for manufacturing a semiconductor device including a semiconductor element and a wire electrically connected to the semiconductor element.

### Description of the Background Art

Examples of a method for manufacturing a semiconductor device including a chip-shaped semiconductor element and a wire electrically connected to the semiconductor element include a method for manufacturing a semiconductor package disclosed in International Publication No. WO 2016/051449.

This manufacturing method is configured to perform surface treatment on surfaces of a die pad, a semiconductor element, a connection member, and a lead in a semiconductor package with a silane coupling agent to be a primary layer. The surface of the semiconductor element includes a first surface to which the connection member is bonded, the first surface including a first region where an organic substance is exposed and a second region where an inorganic substance is exposed, and bonding strength between the first region and sealing resin is weaker than bonding strength between the second region and the sealing resin.

Examples of a semiconductor device using a primary composition include an optical semiconductor device disclosed in Japanese Patent Application Laid-Open No. 2014-22669. This optical semiconductor device is formed by bonding a substrate equipped with an optical semiconductor element to a sealant made of an addition reaction curable silicone composition that seals the optical semiconductor element.

This optical semiconductor device includes a primer composition for bonding the substrate to the sealant, the primer composition containing an alkoxysilane compound having at least one mercapto group in one molecule, a titanium compound, and a solvent.

The conventional techniques disclosed in International Publication No. WO 2016/051449 and Japanese Patent Application Laid-Open No. 2014-22669 use a spinner or a sprayer to apply a coating liquid that is to be a constituent material of a primary layer or a primary composition. Thus, when the coating liquid is applied using the spinner after the semiconductor element and the like are attached to a case, a liquid pool is generated on an inner wall of the case to generate a film thickness region including a primary layer formed with a relatively large film thickness, thereby causing insufficient reaction in the film thickness region.

In contrast, when a pre-coating process is used in which the coating liquid is applied before the semiconductor element or the like is attached to the case, the pre-coating process affects adhesion between the case attached thereafter and a substrate equipped with the semiconductor element, and strength of a wire bonded to the semiconductor element. Thus, using the pre-coating process is undesirable.

When droplets of the coating liquid are applied from above by the atomizer, the coating liquid is less likely to be applied to a back surface of the wire, the back surface being to be bonded, thereby causing a manufactured semiconductor device to have a structure in which the back surface of the wire is provided with no primary layer.

Thus, when a sealant such as a sealing resin is formed to cover the semiconductor element and the wire, bonding strength between the back surface of the bonded wire and the sealant is weakened to cause the back surface to be a starting point from which the sealant peels when thermal stress is generated during use of the semiconductor device.

When a coating process is performed by scattering the coating liquid in a mist form, the coating liquid is less likely to be uniformly applied over the entire outer periphery of the wire, and then the coating liquid may be applied to a region where application of the coating liquid is prohibited.

As described above, the conventional method for manufacturing a semiconductor device, including the step of covering the semiconductor element and the like with the sealant after forming the primary layer, causes a problem in that forming a primary layer on the outer periphery of the wire bonded to the semiconductor element is substantially impossible.

### SUMMARY

Provided is a method for manufacturing a semiconductor device, capable of accurately forming a primary layer on an outer periphery of a wire.

A method for manufacturing a semiconductor device of the present disclosure includes steps (a) to (c).

The step (a) is performed to prepare a coating target structure including a semiconductor element and a wire electrically connected to the semiconductor element.

The step (b) is performed to perform a coating process of supplying a coating liquid from a coating liquid supply port toward the coating target structure using a nozzle disposed above the coating target structure and having the coating liquid supply port.

The step (c) is performed to dry the coating target structure after the step (b) is performed.

The coating liquid contains a silane coupling agent.

The nozzle has a transport wind generating function of generating a liquid transport wind that spirally swirls downward, and the coating liquid is supplied to the coating target structure along a flow of the liquid transport wind.

The nozzle used in the method for manufacturing a semiconductor device of the present disclosure generates the spiral liquid transport wind and supplies the coating liquid to the coating target structure along a flow of the liquid transport wind.

Thus, after the step (b) is performed, the coating liquid can be applied to the outer periphery of the wire including the back surface of the wire.

As a result, the method for manufacturing a semiconductor device of the present disclosure enables the primary layer containing the silane coupling agent as a constituent material to be accurately formed on the outer periphery of the wire including the back surface of the wire after the step (c) is performed.

These and other objects, features, aspects and advantages of the present disclosure will become more apparent from the following detailed description of the present disclosure when taken in conjunction with the accompanying drawings.

### BRIEF DESCRIPTION OF THE DRAWINGS

FIG. 1 is a sectional view illustrating a structure of a semiconductor device manufactured by a method for manufacturing a semiconductor device according to a first preferred embodiment of the present disclosure;

FIG. 2 is a flowchart illustrating a processing procedure of the method for manufacturing a semiconductor device according to the first preferred embodiment;

FIG. 3 is an explanatory diagram schematically illustrating a state of a coating process with a nozzle used in the method for manufacturing a semiconductor device according to the first preferred embodiment;

FIG. 4 is an explanatory diagram schematically illustrating a planar structure of a bottom surface of the nozzle illustrated in FIG. 3 as viewed from below;

FIG. 5 is an explanatory diagram schematically illustrating a sectional structure of the nozzle illustrated in FIG. 4 taken along line A-A;

FIG. 6 is an explanatory diagram showing a verification result of bonding strength with a primary layer in a table format;

FIG. 7 is an explanatory diagram schematically illustrating a state of a coating process with a nozzle used in a method for manufacturing a semiconductor device according to a second preferred embodiment;

FIG. 8 is an explanatory diagram schematically illustrating an ultrasonic vibration function of a nozzle used in a method for manufacturing a semiconductor device according to a third preferred embodiment;

FIG. 9 is an explanatory diagram schematically illustrating a state of a coating process with a nozzle used in a method for manufacturing a semiconductor device according to a fourth preferred embodiment; and

FIG. 10 is an explanatory diagram schematically illustrating a planar structure of the nozzle illustrated in FIG. 9 as viewed from above.

### DESCRIPTION OF THE PREFERRED EMBODIMENTS

### First Preferred Embodiment

### (Semiconductor Device)

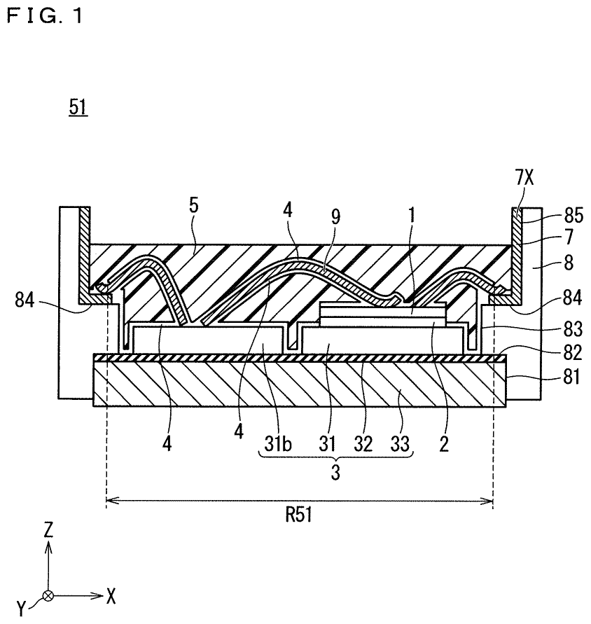

FIG. 1 is a sectional view illustrating a structure of a semiconductor device 51 manufactured by a method for manufacturing a semiconductor device according to a first preferred embodiment of the present disclosure. FIG. 1 illustrates an XYZ orthogonal coordinate system.

As illustrated in the drawing, the semiconductor device 51 includes a semiconductor element 1, a bonding material 2, a resin insulating substrate 3, a primary layer 4, a plurality of wires 9, a sealant 5, and a case 8 as main components. The case 8 accommodates the semiconductor element 1, the bonding material 2, the resin insulating substrate 3, the primary layer 4, the plurality of wires 9, and the sealant 5.

The resin insulating substrate 3 includes circuit patterns 31 and 31b, a resin insulating layer 32, and a base plate 33 as main components. The resin insulating layer 32 is provided on the base plate 33, and the circuit patterns 31 and 31b are selectively provided on the resin insulating layer 32.

The semiconductor element 1 is provided as a power semiconductor chip on the circuit pattern 31 with the bonding material 2 interposed therebetween. The case 8 accommodates the resin insulating substrate 3 while fixing a side surface of the resin insulating substrate 3 and a part of an upper surface of the resin insulating layer 32. Specifically, the resin insulating substrate 3 is fixed in the case 8 such that a lower side surface 81 of the case 8 is in contact with the base plate 33 and a part of a side surface of the resin insulating layer 32, and an intermediate lower surface 82 of the case 8 is in contact with a part of an upper surface of resin insulating layer 32.

The case 8 is provided on an intermediate upper surface 84 with a signal terminal 7 functioning as an electrode of the semiconductor device 51. FIG. 1 illustrates two signal terminals 7. The signal terminal 7 includes a bottom part and an upper erected part bent from the bottom part. The bottom part is provided on the intermediate upper surface 84, and the upper erected part extends upward in a Z direction and is in contact with an upper side surface 85 of the case 8.

The semiconductor element 1 is electrically connected on its upper surface to an upper surface of the circuit pattern 31b with the wire 9. The upper surface of the circuit pattern 31b is electrically connected to the bottom part of the signal terminal 7 on the left in the drawing with the wire 9, and the upper surface of the semiconductor element 1 is electrically connected to the bottom part of the signal terminal 7 on the right in the drawing with the wire 9. As described above, FIG. 1 illustrates three wires 9 as the plurality of wires 9.

Each wire 9 has ends that are bonded to any one of the upper surface of the semiconductor element 1, the upper surface of the circuit pattern 31b, and the upper surfaces of the bottom parts of the respective signal terminals 7 on the left and right by a wire bonding process. The three wires 9 illustrated in FIG. 1 have respective arc shapes that are substantially equal in loop height.

The primary layer 4 is provided on a part of the intermediate upper surface 84 of the case 8, the intermediate side surface 83, a side surface and the upper surface of the circuit pattern 31b, and the upper surface of the semiconductor element 1, in a coating target region R51. The primary layer 4 is also provided on outer peripheries of the respective plurality of wires 9 including back surfaces of the respective plurality of wires 9 in the coating target region R51. That is, the primary layer 4 is provided on the entire circumference of each wire 9. The primary layer 4 uses a silane coupling agent as a constituent material, and functions as a base layer for bonding to the sealant 5.

The sealant 5 is provided covering the circuit patterns 31 and 31b, the semiconductor element 1, the bonding material 2, the primary layer 4, the wires 9, and a part of the signal terminal 7. The signal terminal 7 includes a part of the upper erected part, the part being exposed from the sealant 5 to have an exposed region serving as an external terminal region 7X.

### (Method for Manufacturing Semiconductor Device)

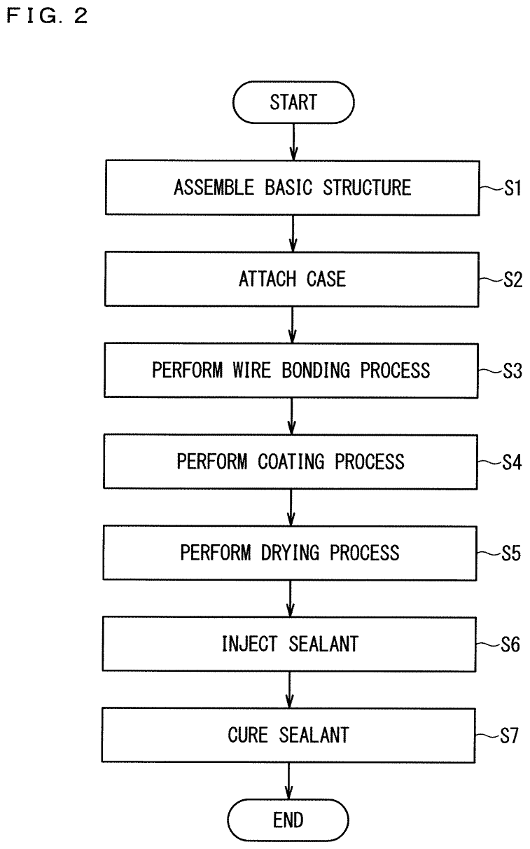

FIG. 2 is a flowchart illustrating a processing procedure of the method for manufacturing a semiconductor device according to the first preferred embodiment. Hereinafter, processing contents of the method for manufacturing a semiconductor device according to the first preferred embodiment will be described with reference to the drawing.

In step S1, a basic structure of the semiconductor device 51 is first assembled. The basic structure means a structure including the resin insulating substrate 3, the bonding material 2, and the semiconductor element 1.

Hereinafter, a method for assembling the basic structure will be described. First, the resin insulating layer 32 is applied to copper foil before patterning, and the base plate 33 is further attached to the resin insulating layer 32. Then, the resin insulating layer 32 is reacted by hot pressing and annealing to bond the copper foil and the resin insulating layer 32, and the resin insulating layer 32 and the base plate 33.

After that, the copper foil is etched to form the circuit patterns 31 and 31b, thereby completing the resin insulating substrate 3. Then, the semiconductor element 1 is mounted on the resin insulating substrate 3 with the bonding material 2 interposed therebetween to bond the semiconductor element 1 and the circuit pattern 31 with the bonding material 2 by heat treatment. As a result, the basic structure including the resin insulating substrate 3, the bonding material 2, and the semiconductor element 1 is completed.

Before step S1 is performed, processing may be performed provide a bump for height adjustment in the basic structure on the semiconductor element 1 or the circuit pattern 31b.

After step S1 is performed, the case 8 is attached to the basic structure in step S2. Specifically, the case 8 is attached to the basic structure by bonding a part of the upper surface of the resin insulating layer 32 to the intermediate lower surface 82 of the case 8 with an adhesive. The case 8 attached in step S2 includes the signal terminal 7 on the intermediate upper surface 84.

In subsequent step S3, a wire bonding process is performed to provide the plurality of wires 9 on the basic structure and the signal terminal 7. The plurality of wires 9 electrically connect the semiconductor element 1, the signal terminal 7, and the circuit pattern 31b to one another.

After step S3 is performed, the coating target structure is completed in which the resin insulating substrate 3, the bonding material 2, the semiconductor element 1, the signal terminal 7, and the wire 9 are housed in the case 8. As described above, steps S1 to S3 are performed to prepare the coating target structure including the semiconductor element 1 and the wires 9 electrically connected to the semiconductor element 1.

The processing procedure of the method for manufacturing a semiconductor device illustrated in FIG. 2 causes the wire bonding process to be performed in step S3 after the case is attached in step S2. That is, the wire bonding process is performed once.

A modification may be performed in which the wire bonding process is separately performed as first bonding process and second wire bonding process. That is, instead of the processing procedure of steps S2 and S3 illustrated in FIG. 2, a processing procedure, “performing processing of attaching a case after the first wire bonding process is performed, and then performing the second wire bonding process” may be used as the modification. The modification enables increasing the number of steps of the wire bonding process.

In subsequent step S4, a coating process for the coating target structure is performed using a nozzle 10.

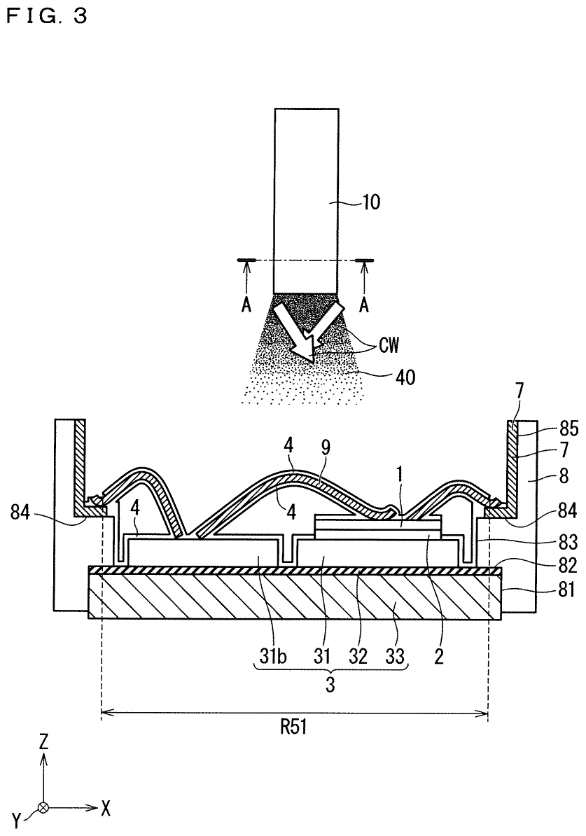

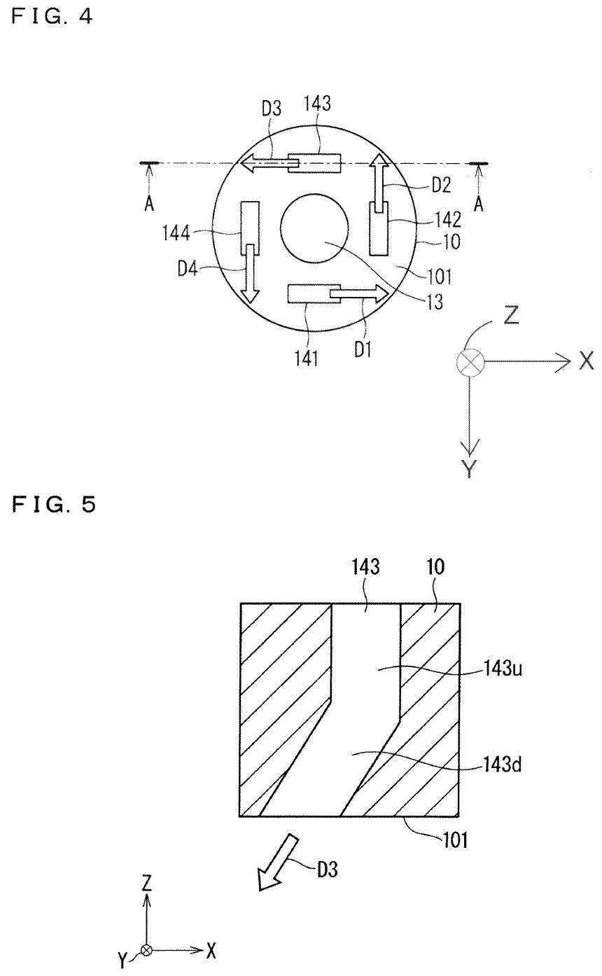

FIG. 3 is an explanatory diagram schematically illustrating a state of the coating process using the nozzle 10 in step S4. FIG. 4 is an explanatory diagram schematically illustrating a planar structure of a bottom surface of the nozzle 10 as viewed from below. FIG. 5 is an explanatory diagram schematically illustrating a sectional structure of the nozzle 10 illustrated in FIG. 4 taken along line A-A. FIGS. 3 to 5 illustrate respective XYZ orthogonal coordinate systems.

As illustrated in FIG. 4, a coating liquid supply port 13 is provided at the center of a bottom surface 101 of the nozzle 10. When a coating liquid 40 is discharged downward in the −Z direction from the coating liquid supply port 13, the coating liquid 40 is supplied to the coating target structure below.

The coating liquid 40 is an alcohol diluent of a silane coupling agent, and the silane coupling agent has a concentration set to 1% or less. Examples of conceivable alcohol include ethanol.

As illustrated in FIG. 4, air supply ports 141 to 144 are uniformly provided on respective four sides of the coating liquid supply port 13 on the XY plane in plan view. Specifically, the air supply ports 141, 142, 143, and 144 are respectively provided on a +Y direction side, a +X direction side, a −Y direction side, and a −X direction side, with respect to the coating liquid supply port 13.

The air supply ports 141 to 144 are provided to eject partial transport winds D1 to D4, respectively. Each of the partial transport winds D1 to D4 is ejected in an obliquely downward direction, or each of the partial transport winds D1 to D4 has directivity in a downward and oblique direction with respect to the horizontal direction.

Specifically, the partial transport wind D1 has the directivity downward and toward the +X direction, the partial transport wind D2 has the directivity downward and toward the −Y direction, the partial transport wind D3 has the directivity downward and toward the −X direction, and the partial transport wind D4 has the directivity downward and toward the +Y direction.

As illustrated in FIG. 5, the air supply port 143 includes an upper supply port 143u and a lower supply port 143d. The air supply port 143 receives air for the partial transport wind D3, the air being supplied from a supply source (not illustrated). The air supplied from the supply source flows downward through the upper supply port 143u, and is further ejected as the partial transport wind D3 from the bottom surface 101 through the lower supply port 143d.

The upper supply port 143u is formed along the Z direction. The lower supply port 143d is inclined in the horizontal direction toward the −Z direction. Specifically, the lower supply port 143d is inclined downward in the −X direction. Thus, the partial transport wind D3 finally ejected from the lower supply port 143d has directivity downward and toward the −X direction, reflecting the shape of the lower supply port 143d.

The air supply ports 141,142 and 144 are each also similar in structure to the air supply port 143, and respectively eject the partial transport winds D1, D2, and D4 each having the directivity described above. The partial transport winds D1 to D4 are usually supplied from one supply source, and the one supply source supplies air to each of the air supply ports 141 to 144.

As described above, each of the air supply ports 141 to 144 has the internal structure described above, so that the partial transport winds D1 to D4 each having the directivity described above can be ejected from the bottom surface 101 of the nozzle 10.

Thus, as a result of the partial transport winds D1 to D4 each having directivity in a downward and oblique direction with respect to the horizontal direction and being ejected from the bottom surface 101 of the nozzle 10, the partial transport winds D1 to D4 are combined to generate the liquid transport wind CW having spiral downward directivity.

As described above, the nozzle 10 has a transport wind generating function of generating the liquid transport wind CW described above. Thus, the coating liquid 40 discharged from the coating liquid supply port 13 of the nozzle 10 is supplied to the coating target structure along the directivity of the liquid transport wind CW. That is, the coating liquid 40 is supplied to the coating target structure in a manner in which the coating liquid 40 is spirally transported by the liquid transport wind CW.

The processing in step S4 described above is performed by appropriately moving the nozzle 10 or the coating target structure to supply the coating liquid 40 to the coating target region R51. When the coating target structure is moved, a pedestal (not illustrated) that supports the coating target structure from below is moved.

As described above, the coating process needs to be performed by changing a placement relationship between the nozzle 10 and the coating target structure, so that a relative movement process between the nozzle 10 and the coating target structure is also performed during a period in which the coating process is performed in step S4.

As described above, the coating process is performed in step S4 by supplying the coating liquid 40 from the coating liquid supply port 13 to the coating target structure using the nozzle 10 disposed above the coating target structure and having the coating liquid supply port 13.

The nozzle 10 used in the coating process in step S4 generates the liquid transport wind CW that spirally swirls downward, and supplies the coating liquid 40 to the coating target region R51 of the coating target structure along a flow of the liquid transport wind CW.

Thus, the coating liquid 40 is applied throughout to an exposed region of the resin insulating layer 32, the upper surface and side surfaces of each of the circuit patterns 31 and 31b, the upper surface of the semiconductor element 1, and the outer periphery of each of the plurality of wires 9, in the coating target region R51.

The coating liquid 40 is transported by the liquid transport wind CW. Thus, the coating liquid 40 can be supplied to each of the plurality of wires 9 so that the coating liquid 40 hit the corresponding one of the plurality of wires 9 from the horizontal direction.

As a result, the coating liquid 40 can also adhere to a lower side including a back surface of each of the plurality of wires 9, so that the coating liquid 40 can be applied throughout to the entire outer periphery of each of the wires 9.

After step S4 is performed, a drying process in step S5 is performed. The drying process is performed on the coating target structure after step S4 is performed at a drying temperature of about 180° C. to 220° C. and with a drying time of about 0.5 to 4.0 hours.

As a result, the primary layer 4 is formed on the exposed region of the resin insulating layer 32, the upper surface and the side surfaces of each of the circuit patterns 31 and 31b, the upper surface of the semiconductor element 1, and the outer periphery of each of the plurality of wires 9, in the coating target region R51 as illustrated in FIG. 3. The primary layer 4 contains a silane coupling agent as a constituent material.

The primary layer 4 formed after the drying process in step S5 has a film thickness smaller than a film thickness of the coating liquid 40 adhering to the wires 9 or the like after the coating process is performed in step S4.

The film thickness of the primary layer 4 can be adjusted by a supply flow rate of the coating liquid 40 from the nozzle 10, the drying time of the drying process in step S5, and the like.

Returning to FIG. 2, the sealant 5 is injected in step S6 after step S5 is performed, and a curing process of the sealant 5 is performed in step S7. As a result, the semiconductor device 51 having the structure illustrated in FIG. 1 can be completed.

### (Verification Result)

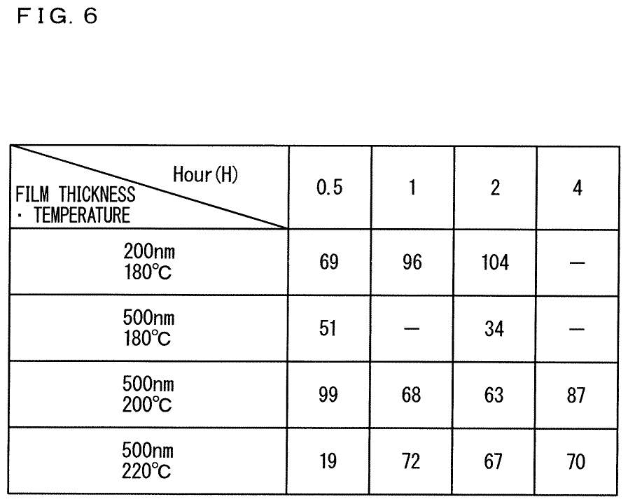

FIG. 6 is an explanatory diagram showing a verification result of the bonding strength of the primary layer 4 manufactured by the drying process in step S5 in a tabular form.

FIG. 6 shows drying temperatures of 180° C., 200° C., and 220° C. and drying times of 0.5 H (Hour), 1 H, 2 H, and 4 H, which are used in the drying process. FIG. 6 shows film thicknesses of respective primary layers 4 after the drying process is performed in step S5.

FIG. 6 shows numerical values each of which represents bonding strength of the completed semiconductor device 51 having been stored in a high-temperature and high-humidity environment. The term “bonding strength” means bonding strength between the sealant 5 and the primary layer 4. The bonding strength is indicated by numerical values including an initial value of “100” indicating a state immediately after completion of the semiconductor device 51. This reveals that bonding strength indicated by a numerical value closer to “100” shows less deterioration from the initial state.

As shown in the second line of FIG. 6, the primary layer 4 having a film thickness of 200 nm obtained at a drying temperature of 180° C. has a numerical value of “96” in a drying time of 1 hour, thereby finding a small deterioration, and has a numerical value of “104” in a drying time of 2 hours, thereby finding an improved bonding strength.

As shown in the third line of FIG. 6, the primary layer 4 having a film thickness of 500 nm obtained at a drying temperature of 180° C. shows that a good drying time with a small deterioration in bonding strength is not particularly found. Considerable causes include insufficient reaction of the coating liquid 40 to be the primary layer 4 at the drying temperature of 180° C., the insufficient reaction deteriorating the strength in the primary layer 4.

As shown in the fourth line of FIG. 6, the primary layer 4 having a film thickness of 500 nm obtained at a drying temperature of 200° C. has a numerical value of “99” in a drying time of 0.5 hours, thereby finding a small deterioration.

As shown in the last line of FIG. 6, the primary layer 4 having a film thickness of 500 nm obtained at a drying temperature of 220° C. shows that a good drying time with a small deterioration in bonding strength is not particularly found. Considerable causes include separation of a functional group on the outermost surface of the primary layer 4 at a drying temperature of 220° C., the separation deteriorating strength of an interface of the primary layer 4.

The verification result illustrated in FIG. 6 derives an estimation in which when the film thickness of the primary layer 4 is set to an ideal film thickness of 200 nm to 500 nm, it is desirable to set the drying temperature to 190° C. to 210° C. and the drying time to about 15 to 45 minutes to suppress deterioration of the bonding strength.

The condition of the drying temperature {190° C. to 210° C.} is presumed to be a condition in which formation of a crosslink and separation of a functional group in a film necessary for securing the bonding strength with the sealant 5 are balanced in an ideal film thickness of 200 to 500 nm of the primary layer 4.

The term “crosslink” means a bond between molecules of the silane coupling agent serving as a constituent material of the primary layer 4. The “functional group” is NH₂ in the case of a silane coupling agent of an amino group. Thus, the term “separation of a functional group” means that {NH₂} disappears by heat treatment. When the functional group is separated, the number of sites of reaction with the sealant 5 decreases, and thus leading to a decrease in strength with the sealant 5.

### (Effect)

As described above, the method for manufacturing a semiconductor device according to the first preferred embodiment includes the coating process in step S4 in which the nozzle 10 having the transport wind generating function is used and generates the liquid transport wind CW in a spiral manner by combining the partial transport winds D1 to D4, and supplying the coating liquid 40 to the coating target structure along a flow caused by the liquid transport wind CW.

Thus, after step S4 is performed, the coating liquid 40 can be applied throughout to the outer periphery including the back surface of each of the plurality of wires 9. That is, the coating liquid 40 can be accurately applied to the entire circumference of each of the plurality of wires 9 existing in the coating target region R51.

As a result, the method for manufacturing a semiconductor device according to the first preferred embodiment enables the primary layer 4 containing the silane coupling agent as a constituent material to be accurately formed on the outer periphery including the back surface of each of the wires 9 after the drying process is performed in step S5. That is, the method for manufacturing a semiconductor device according to the first preferred embodiment enables the primary layer 4 to be provided over the entire outer periphery of each of the plurality of wires 9.

The method for manufacturing a semiconductor device according to the first preferred embodiment also causes a sealing process using the sealant 5 to be performed in steps S6 and S7 to enable obtaining the semiconductor device 51 having a structure in which the sealant protects the semiconductor element 1, the plurality of wires 9, and the primary layer 4.

The semiconductor device 51 includes the primary layer 4 containing a silane coupling agent as a constituent material and being accurately provided on the outer periphery including the back surface of each of the wires 9. Thus, the bonding strength between the wire 9 and the sealant 5 on the entire circumference of each of the wires 9 can be appropriately maintained, and thus enabling reliable avoidance of a phenomenon in which the sealant 5 peels off during use of the semiconductor device 51.

That is, there is no region where the bonding strength is weakened between each of the wires 9 and the sealant 5, thereby causing no starting point at which the sealant 5 peels off when thermal stress is generated during use of the semiconductor device 51. Thus, the sealant 5 does not peel off during the use of the semiconductor device 51.

As a result, the semiconductor device 51 packaged with the sealant 5 has improved resistance to thermal stress during use to enable a longer life.

Then, the coating liquid 40 supplied from the nozzle 10 is an alcohol diluent of a silane coupling agent, and thus satisfies a dilution condition where “the silane coupling agent has a concentration of 1% or less”.

The dilution condition is determined based on study results including wettability of the coating liquid 40 and an optimization of a heat treatment condition in the drying process to be performed in step S5.

Thus, the method for manufacturing a semiconductor device according to the first preferred embodiment enables the coating liquid 40 to be accurately applied to the periphery of each of the wires 9 after the coating process is performed in step S4 by supplying the coating liquid 40 satisfying the dilution condition from the nozzle 10.

### (Transport Wind Generating Function)

The method for manufacturing a semiconductor device according to the first preferred embodiment uses the nozzle 10 that has a transport wind generating function of generating the liquid transport wind CW that spirally swirls downward by combining the partial transport winds D1 to D4. Hereinafter, an aspect in which the liquid transport wind CW is formed by combining the partial transport winds D1 to D4 is defined as a basic aspect.

The generation of the liquid transport wind CW is not limited to the basic aspect described above, and various aspects can be considered. Considerable examples of a minimum necessary aspect for generating the liquid transport wind CW include an aspect of ejecting only the first and second partial transport winds. That is, the liquid transport wind CW in the minimum necessary aspect is a combination of the first and second partial transport winds.

Hereinafter, a condition of the minimum necessary aspect will be described. The nozzle includes a first air supply port for supplying a first partial transport wind, a second air supply port for supplying second partial transport wind, and the coating liquid supply port 13 provided between first and second gas supply ports.

The first partial transport wind has first directivity downward and obliquely in a first direction, and the second partial transport wind has second directivity downward and obliquely in a second direction. Here, the first direction and the second direction face each other.

Considerable examples of the minimum necessary aspect include a first aspect in which the partial transport winds D1 and D3 illustrated in FIGS. 4 and 5 serve as first and second partial transport winds, respectively. That is, the first aspect causes the nozzle 10 to be provided with only the air supply ports 141 and 143, and without the air supply ports 142 and 144.

As described above, the partial transport wind D1 has directivity downward and obliquely in the +X direction serving as the first direction, and the partial transport wind D3 has directivity downward and obliquely in the −X direction serving as the second direction.

The +X direction and the −X direction are opposite to each other, so that the first direction and the second direction face each other.

As described above, the first aspect of the minimum necessary aspect enables generating the liquid transport wind CW in a spiral manner by combining the partial transport winds D1 and D3.

Considerable examples of the minimum necessary aspect include a second aspect in which the partial transport winds D2 and D4 illustrated in FIGS. 4 and 5 serve as first and second partial transport winds, respectively. That is, the second aspect causes the nozzle 10 to be provided with only the air supply ports 142 and 144, and without the air supply ports 141 and 143.

As described above, the partial transport wind D2 has directivity downward and obliquely in the −Y direction serving as the first direction, and the partial transport wind D4 has directivity downward and obliquely in the +Y direction serving as the second direction.

The +Y direction and the −Y direction are opposite to each other, so that the first direction and the second direction face each other.

As described above, the second aspect of the minimum necessary aspect enables generating the liquid transport wind CW in a spiral manner by combining the partial transport winds D2 and D4.

The basic aspect is a combination of the first aspect and the second aspect. Thus, an expansion aspect may be used in which 2n (n is an integer of one or more) partial transport winds are ejected from the nozzle 10 to form an even number of partial transport winds, such as six or eight partial transport winds, by appropriately adding the minimum necessary aspect. For example, when an expansion aspect is used in which eight partial transport winds are ejected from the nozzle 10, eight air supply ports uniformly surrounding the coating liquid supply port 13 in plan view may be provided to form the expansion aspect with four sets of the minimum necessary aspect.

As described above, there are considered the first and second aspects in which the minimum necessary aspect of the nozzle 10 is used in the method for manufacturing a semiconductor device according to the first preferred embodiment. The minimum necessary aspect enables generating the liquid transport wind CW in a spiral manner by supplying the first and second partial transport winds satisfying requirements of the minimum necessary aspect from the first and second air supply ports, respectively.

Thus, the nozzle satisfying the minimum necessary aspect can be fabricated with a relatively simple structure in which the first and second air supply ports are provided in the nozzle, so that manufacturing cost can be reduced.

As illustrated in FIG. 4, the basic aspect causes the four partial transport winds D1 to D4 to be generated. The partial transport winds D1 to D4 have combined directivity in a counterclockwise direction around the coating liquid supply port 13 on the XY plane in plan view.

It is considered that the liquid transport wind CW can also be generated by this combined directivity. Here, an aspect in which the liquid transport wind CW is generated from K (≥3) partial transport winds satisfying the following combination condition is defined as a modified aspect.

The combination condition is as follows: K (≥3) partial transport winds have combined directivity in a common direction around the coating liquid supply port 13 in plan view. The common direction is either clockwise or counterclockwise.

In the modified aspect, K may be an odd number or an even number. For example, when K is three, three air supply ports uniformly surrounding the coating liquid supply port 13 in plan view are provided, and first to third partial transport winds ejected from the respective three air supply ports satisfy the condition “combined directivity in one of clockwise and counterclockwise directions around the coating liquid supply port 13 in plan view”. The basic aspect can also be considered as a modified aspect in which K is four.

### Second Preferred Embodiment

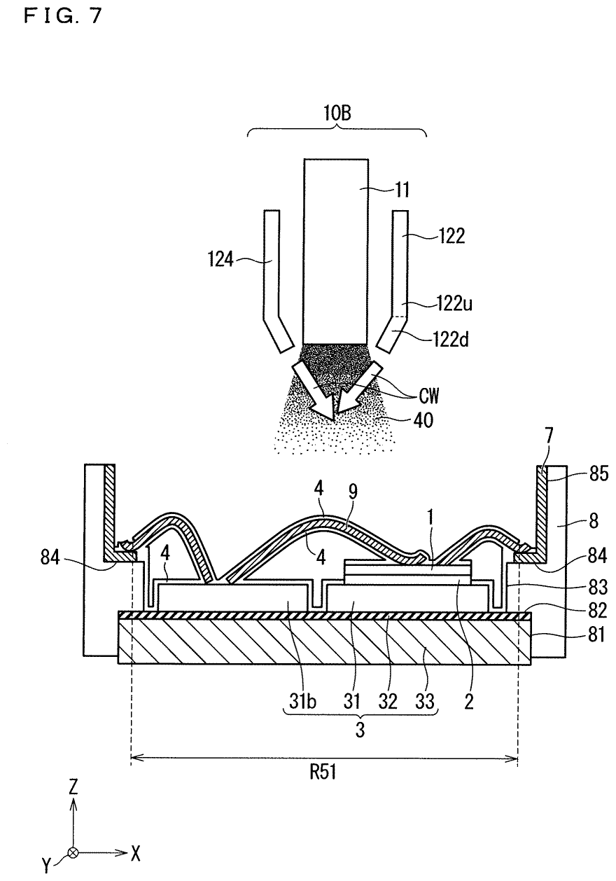

FIG. 7 is an explanatory diagram schematically illustrating a state of a coating process with a nozzle 10B used in a method for manufacturing a semiconductor device according to a second preferred embodiment. FIG. 7 illustrates an XYZ orthogonal coordinate system.

The second preferred embodiment is different from the first preferred embodiment in that the coating process shown in step S4 of FIG. 2 is performed using the nozzle 10B instead of the nozzle 10. Hereinafter, features of the method for manufacturing a semiconductor device according to the second preferred embodiment will be mainly described.

The processing of steps S1 to S3 illustrated in FIG. 2 is performed as in the first preferred embodiment, and then in step S4, the coating process is performed on the coating target structure using the nozzle 10B illustrated in FIG. 7.

The nozzle 10B includes a nozzle body 11 and air ejection pipes 121 to 124 as components. FIG. 7 illustrates only the air ejection pipes 122 and 124. The air ejection pipes 122 and 124 are schematically illustrated and do not match actual structure.

The nozzle body 11 is provided in its bottom surface with a coating liquid supply port (not illustrated). As with the coating liquid supply port 13 provided in the nozzle 10 according to the first preferred embodiment, this coating liquid supply port is provided to supply the coating liquid 40 to the coating target structure below by ejecting the coating liquid 40. The coating liquid 40 has contents similar to those in the first preferred embodiment.

The air ejection pipes 121 to 124 are provided on respective four sides of the nozzle body 11. Specifically, the nozzle body 11 is provided along its −Y direction side with the air ejection pipe 121, its +X direction side with the air ejection pipe 122, its +Y direction side with the air ejection pipe 123, and its −X direction side with the air ejection pipe 124.

The air ejection pipes 121 to 124 are provided to eject partial transport winds D1 to D4, respectively. Each of the partial transport winds D1 to D4 has directivity in a downward and oblique direction with respect to the horizontal direction. Specifically, the partial transport wind D1 has the directivity downward and toward the +X direction, the partial transport wind D2 has the directivity downward and toward the −Y direction, the partial transport wind D3 has the directivity downward and toward the −X direction, and the partial transport wind D4 has the directivity downward and toward the +Y direction.

Each of the air ejection pipes 121 to 124 includes an upper partial pipe above and a lower partial pipe below. For example, the air ejection pipe 122 includes an upper partial pipe 122u and a lower partial pipe 122d as illustrated in FIG. 7.

The upper partial pipe 122u is formed along the Z direction. The lower partial pipe 122d is inclined in the horizontal direction toward the −Z direction. That is, the air ejection pipe 122 is inclined downward in the +Y direction. Thus, the partial transport wind D2 finally ejected from the lower partial pipe 122d has directivity downward and toward the +Y direction, reflecting the inclination of the lower partial pipe 122d.

As described above, the air ejection pipes 121 to 124 of the nozzle 10B according to the second preferred embodiment correspond to the air supply ports 141 to 144 provided in the nozzle 10 according to the first preferred embodiment, respectively, and have a downward inclination in the horizontal direction as with the air supply ports 141 to 144.

Thus, the partial transport winds D1 to D4 ejected from the air ejection pipes 121 to 124, respectively, have the same directivity as the partial transport winds D1 to D4 ejected respectively from the air supply ports 141 to 144 according to the first preferred embodiment. That is, the second preferred embodiment uses the combination of the partial transport winds D1 to D4 as the liquid transport wind CW as in the basic aspect described in the first preferred embodiment.

Then, as a result of the partial transport winds D1 to D4 each having directivity in a downward and oblique direction with respect to the horizontal direction and being ejected from corresponding one of the air ejection pipes 121 to 124, the liquid transport wind CW having spiral downward directivity is generated by combining the partial transport winds D1 to D4 as in the first preferred embodiment. Thus, the coating liquid 40 ejected downward from the nozzle body 11 is supplied to the coating target structure along the directivity of the liquid transport wind CW.

As in the first preferred embodiment, the relative movement process between the nozzle 10B and the coating target structure is also performed during a period in which the coating process is performed in step S4 even in the second preferred embodiment.

Steps S5 to S7 similar to those in the first preferred embodiment are performed after step S4 is performed, so that the semiconductor device 51 having the structure illustrated in FIG. 1 can be completed.

### (Transport Wind Generating Function)

The method for manufacturing a semiconductor device according to the second preferred embodiment uses the nozzle 10B that has a transport wind generating function of generating the liquid transport wind CW in a spiral manner by combining the partial transport winds D1 to D4. As with the nozzle 10 according to the first preferred embodiment, the nozzle 10B has the transport wind generating function according to the basic aspect of generating the partial transport winds D1 to D4.

Thus, the nozzle 10B according to the second preferred embodiment can generate the liquid transport wind CW even when the aspect is changed to the minimum necessary aspect, as with the nozzle 10 according to the first preferred embodiment.

Hereinafter, a condition of the minimum necessary aspect in the second preferred embodiment will be described. The nozzle includes a first air ejection pipe for supplying a first partial transport wind, a second air ejection pipe for supplying a second partial transport wind, and the nozzle body 11 that has a coating liquid supply port and is provided between the first and second air ejection pipes. The first air ejection pipe functions as a first air supply member for supplying the first partial transport wind, and the second air ejection pipe functions as a second air supply member for supplying the second partial transport wind.

The first partial transport wind has first directivity downward and obliquely in a first direction, and the second partial transport wind has second directivity downward and obliquely in a second direction. Here, the first direction and the second direction face each other.

Considerable examples of a first aspect of the minimum necessary aspect include a configuration in which the nozzle 10B is provided with only the air ejection pipes 121 and 123 and without the air ejection pipes 122 and 124. That is, the first aspect has a configuration in which the first and second air supply members serve as the air ejection pipes 121 and 123, respectively.

Considerable examples of a second aspect of the minimum necessary aspect include a configuration in which the nozzle 10B is provided with only the air ejection pipes 122 and 124 and without the air ejection pipes 121 and 123. That is, the second aspect has a configuration in which the first and second air supply members serve as the air ejection pipes 122 and 124, respectively.

Thus, an expansion aspect may be used in which 2n (n is an integer of one or more) partial transport winds are ejected from 2n air ejection pipes to form an even number of partial transport winds, such as six or eight partial transport winds, by appropriately adding the minimum necessary aspect even in the second preferred embodiment.

As described above, there are considered the first and second aspects in which the minimum necessary aspect of the nozzle 10B is used in the method for manufacturing a semiconductor device according to the second preferred embodiment. The minimum necessary aspect enables generating the liquid transport wind CW in a spiral manner by supplying the first and second partial transport winds satisfying requirements of the minimum necessary aspect from the first and second air ejection pipes, respectively.

Thus, the nozzle 10B satisfying the minimum necessary aspect can be fabricated with a relatively simple structure with the nozzle body 11, and the first and second air ejection pipes, so that manufacturing cost can be reduced.

Even the nozzle 10B according to the second preferred embodiment can use a modified aspect similar to that of the nozzle 10 according to the first preferred embodiment.

### Third Preferred Embodiment

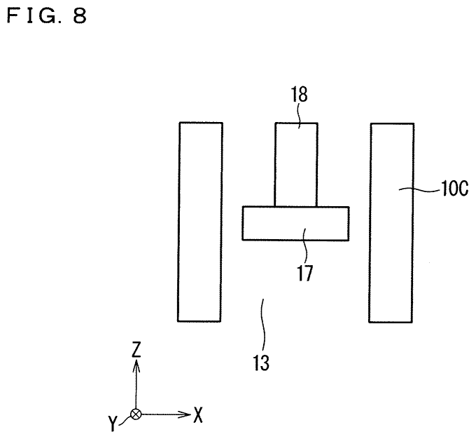

FIG. 8 is an explanatory diagram schematically illustrating an ultrasonic vibration function of a nozzle 10C used in a method for manufacturing a semiconductor device according to a third preferred embodiment. FIG. 8 illustrates an XYZ orthogonal coordinate system.

As illustrated in the drawing, the nozzle 10C is provided with a head 17 and a conduit 18 in a coating liquid supply port 13. FIG. 8 locally illustrates the coating liquid supply port 13 and a peripheral region thereof in the nozzle 10C.

The third preferred embodiment is different from the first preferred embodiment in that the coating process shown in step S4 of FIG. 2 is performed using the nozzle 10C instead of the nozzle 10. Hereinafter, features of the method for manufacturing a semiconductor device according to the third preferred embodiment will be mainly described.

Processing similar to the processing of steps S1 to S3 of the first preferred embodiment shown in FIG. 2 is performed, and then in step S4, the coating process is performed on the coating target structure using the nozzle 10C illustrated in FIG. 8.

Hereinafter, an ultrasonic vibration function of the nozzle 10C illustrated in FIG. 8 will be described in detail. An ultrasonic oscillator (not illustrated) generates an electric signal, and the electric signal is transmitted to the head 17 via the conduit 18. Then, the head 17 vibrates in response to the electric signal as an ultrasonic vibrator, and ultrasonic vibration caused by the head 17 is applied to a coating liquid flowing through the coating liquid supply port 13. At this time, the ultrasonic wave has a vibration frequency set to 60 to 120 kHz.

As a result, the coating liquid 40 in the coating liquid supply port 13 is atomized as a fine and uniform droplet with a diameter of about 20 to 30 μm, and is supplied downward from the coating liquid supply port 13. As described above, the nozzle 10C has an ultrasonic vibration function for atomizing the coating liquid 40.

As with the nozzle 10 according to the first preferred embodiment, the nozzle 10C is provided with four air supply ports corresponding to the air supply ports 141 to 144 on respective four sides of the coating liquid supply port 13. Instead of providing a plurality of air supply ports in the nozzle 10C, four air ejection pipes corresponding to the air ejection pipes 121 to 124 according to the second preferred embodiment may be provided around the nozzle 10C.

Thus, four partial transport winds ejected from the four air supply ports have the same directivity as the partial transport winds D1 to D4 of the first preferred embodiment or the second preferred embodiment. That is, the nozzle 10C according to the third preferred embodiment has a transport wind generating function in which a combination of four partial transport winds serves as the liquid transport wind CW, as in the basic aspects of the first and second preferred embodiments.

Then, as a result of the four partial transport winds each having directivity in a downward and oblique direction with respect to the horizontal direction and being ejected from corresponding one of the four air supply ports of the nozzle 10C, the liquid transport wind CW having spiral directivity is generated by a combination of the four partial transport winds as in the first and second preferred embodiments. Thus, the coating liquid 40 in a minute droplet state supplied from the bottom surface of the nozzle 10C is supplied to the coating target structure along the directivity of the liquid transport wind CW.

As in the first preferred embodiment, the relative movement process between the nozzle 10C and the coating target structure is also performed during a period in which the coating process is performed in step S4 even in the third preferred embodiment.

Steps S5 to S7 similar to those in the first preferred embodiment are performed after step S4 is performed, so that the semiconductor device 51 having the structure illustrated in FIG. 1 can be acquired.

As described above, the nozzle 10C used in the method for manufacturing a semiconductor device according to the third preferred embodiment further has the ultrasonic vibration function, so that the coating liquid 40 with a fine and uniform droplet with a diameter of about 20 to 30 μm can be supplied while the coating process is performed in step S4.

Thus, the method for manufacturing a semiconductor device according to the third preferred embodiment enables the coating liquid to be more accurately applied to the outer periphery of each of the plurality of wires 9 while the coating process is performed in step S4.

As a result, the semiconductor device 51 manufactured by the method for manufacturing a semiconductor device according to the third preferred embodiment enables the primary layer 4 to be more stably formed over the entire circumference of each of the wires 9.

### Fourth Preferred Embodiment

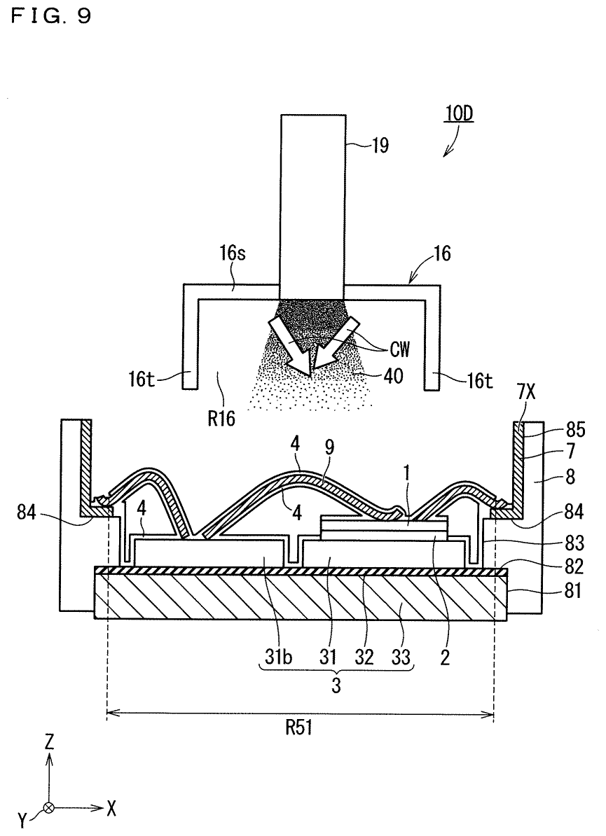

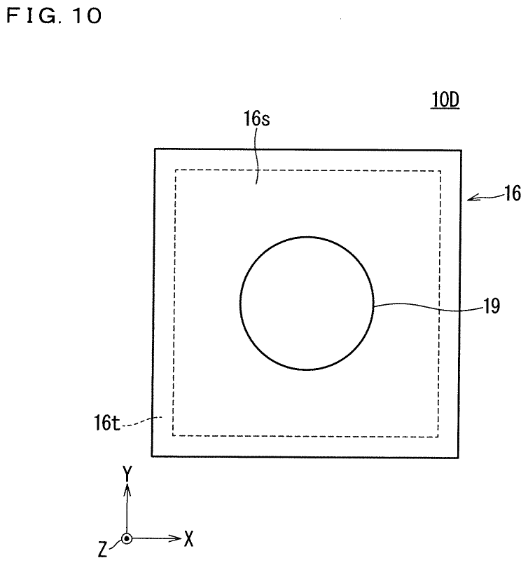

FIG. 9 is an explanatory diagram schematically illustrating a state of a coating process with a nozzle 10D used in a method for manufacturing a semiconductor device according to a fourth preferred embodiment. FIG. 10 is an explanatory diagram schematically illustrating a planar structure of the nozzle 10D illustrated in FIG. 9 as viewed from above. FIGS. 9 and 10 illustrate respective XYZ orthogonal coordinate systems.

The fourth preferred embodiment is different from the first preferred embodiment in that the coating process shown in step S4 of FIG. 2 is performed using the nozzle 10D instead of the nozzle 10. Hereinafter, features of the method for manufacturing a semiconductor device according to the fourth preferred embodiment will be mainly described.

The processing of steps S1 to S3 illustrated in FIG. 2 is performed as in the first preferred embodiment, and then in step S4, the coating process is performed on the coating target structure using the nozzle 10D illustrated in FIG. 9.

As illustrated in FIGS. 9 and 10, the nozzle 10D includes a nozzle body 19 and a cover member 16 as main components. The cover member 16 is provided in a form in which its cover upper surface 16s is disposed in a peripheral region of a lower end of nozzle body 19.

As illustrated in FIG. 10, the cover upper surface 16s of the cover member 16 has a square shape in plan view. The cover upper surface 16s has a planar structure that is formed assuming that the coating target structure has a planar structure in a rectangular shape. The planar structure of the cover upper surface 16s is not limited to the square shape, and may be a rectangular shape or a circular shape other than the square shape.

Cover protrusions 16t are provided in respective four peripheral regions of the cover upper surface 16s in plan view, and are provided protruding downward in the −Z direction as illustrated in FIG. 9.

As described above, the nozzle 10D includes the cover member 16 around the nozzle body 11, so that a supply region of the coating liquid 40 can be limited in a cover inner region R16 surrounded by the cover protrusions 16t.

The nozzle body 19 is provided in its bottom surface with a coating liquid supply port (not illustrated). As with the coating liquid supply port 13 provided in the nozzle 10 according to the first preferred embodiment, this coating liquid supply port is provided to supply the coating liquid 40 to the coating target structure below by ejecting the coating liquid 40.

As with the nozzle 10 according to the first preferred embodiment, the nozzle 10D is provided with four air supply ports corresponding to the air supply ports 141 to 144 on respective four sides of the coating liquid supply port. Instead of providing a plurality of air supply ports in the nozzle body 19, four air ejection pipes corresponding to the air ejection pipes 121 to 124 according to the second preferred embodiment may be provided around the nozzle body 19.

Thus, four partial transport winds ejected from the four air supply ports have the same directivity as the partial transport winds D1 to D4 of the first preferred embodiment and the second preferred embodiment. That is, the nozzle 10D according to the fourth preferred embodiment has a transport wind generating function in which a combination of four partial transport winds serves as the liquid transport wind CW, as in the basic aspects of the first and second preferred embodiments.

Then, as a result of the four partial transport winds each having directivity in a downward and oblique direction with respect to the horizontal direction and being ejected from corresponding one of the four air supply ports of the nozzle 10D, the liquid transport wind CW having spiral directivity is generated by a combination of the four partial transport winds as in the first and second preferred embodiments. Thus, the coating liquid 40 ejected from the bottom surface nozzle body 19 is supplied to the coating target structure along the directivity of the liquid transport wind CW.

As in the first preferred embodiment, the relative movement process between the nozzle 10D and the coating target structure is also performed during a period in which the coating process is performed in step S4 even in the fourth preferred embodiment.

At this time, the nozzle 10D includes the cover member 16 that limits the supply region of the coating liquid 40 into the cover inner region R16, so that the coating liquid 40 can be accurately supplied only into the coating target region R51.

That is, the coating liquid 40 can be accurately supplied into the coating target region R51 by not only appropriately setting a distance between the nozzle 10D and the coating target structure and a supply flow rate of the coating liquid 40, but also appropriately performing the relative movement process.

Steps S5 to S7 similar to those in the first preferred embodiment are performed after step S4 is performed, so that the semiconductor device 51 having the structure illustrated in FIG. 1 can be completed.

The nozzle 10D used in the method for manufacturing a semiconductor device according to the fourth preferred embodiment includes the cover member 16, so that the coating process can be performed with high accuracy in step S4 to prevent the coating liquid 40 from being supplied to regions other than the coating target region R51 on the coating target structure.

As a result, the method for manufacturing a semiconductor device according to the fourth preferred embodiment allows the signal terminal 7 functioning as an external terminal to be disposed outside the coating target region R51 to enable the primary layer 4 to be reliably prevented from being formed on the signal terminal 7, for example, so that the semiconductor device 51 can be manufactured without performance deterioration.

Although the external terminal region 7X of the signal terminal 7 is electrically connected to external wiring or the like by soldering or the like, the primary layer 4 adhering to the external terminal region 7X may disturb electrical connection with the external wiring or the like.

The method for manufacturing a semiconductor device according to the fourth preferred embodiment uses the nozzle 10D for performing the coating process and the nozzle 10D includes the cover member 16, and thus prevents a problem as described above from occurring.

Additionally, the nozzle 10D itself includes the cover member 16. Thus, even when a product size of the semiconductor device to be manufactured is changed, the coating process can be performed in step S4 using the nozzle 10D without replacement.

The product size of the semiconductor device mainly means an occupied area on the XY plane. Thus, when the product size of the semiconductor device is changed, the occupied area of the coating target structure is inevitably changed.

However, the change in the occupied area of the coating target structure can be handled by changing contents of the relative movement process between the nozzle 10D and the coating target structure even using the cover member 16 of the nozzle 10D without replacement.

In contrast, when the coating target structure is provided with a device-side cover member surrounding the coating target region R51, the device-side cover member needs to be replaced with a device-side cover member different in size every time the product size of the semiconductor device to be manufactured is changed.

As described above, the method for manufacturing a semiconductor device according to the fourth preferred embodiment does not require the cover member 16 of the nozzle 10D to be replaced even when the product size of the semiconductor device to be manufactured is changed, and thus enables improvement in workability.

### Others

The present disclosure allows each preferred embodiment to be freely combined, and each preferred embodiment to be appropriately modified or eliminated within the scope of the disclosure.

For example, the ultrasonic vibration function of the nozzle 10C according to the third preferred embodiment may be used for the nozzle 10 according to the first preferred embodiment, the nozzle 10B according to the second preferred embodiment, or the nozzle 10D according to the fourth preferred embodiment.

Alternatively, the cover member 16 of the nozzle 10D according to the fourth preferred embodiment may be attached to the nozzle 10 according to the first preferred embodiment or the nozzle 10C according to the third preferred embodiment.

Hereinafter, various aspects of the present disclosure will be collectively described as supplements.

### Supplement 1

A method for manufacturing a semiconductor device, the method including the steps of:
(a) preparing a coating target structure including a semiconductor element and a wire electrically connected to the semiconductor element;
(b) performing a coating process of supplying a coating liquid from a coating liquid supply port toward the coating target structure using a nozzle disposed above the coating target structure and having the coating liquid supply port; and
(c) drying the coating target structure after the step (b) is performed;
the coating liquid containing a silane coupling agent,
the nozzle having a transport wind generating function of generating a liquid transport wind that spirally swirls downward, and
the coating liquid being supplied to the coating target structure along a flow of the liquid transport wind.

### Supplement 2

The method for manufacturing a semiconductor device according to supplement 1, wherein
the coating liquid is an alcohol diluent of a silane coupling agent, and
the silane coupling agent has a concentration of 1% or less.

### Supplement 3

The method for manufacturing a semiconductor device according to supplement 1 or 2, wherein
the nozzle further includes:
a cover member provided to limit a supply region of the coating liquid below the nozzle.

### Supplement 4

The method for manufacturing a semiconductor device according to any one of supplements 1 to 3, wherein
the nozzle includes:
an ultrasonic vibration function of forming the coating liquid into droplets with an ultrasonic wave of 60 to 120 kHz.

### Supplement 5

The method for manufacturing a semiconductor device according to any one of supplements 1 to 4, wherein
the liquid transport wind includes a combination of first and second partial transport winds, and
the nozzle further includes:
a first air supply port provided to supply the first partial transport wind; and
a second air supply port provided to supply the second partial transport wind,
the coating liquid supply port is provided between the first and second air supply ports,
the first partial transport wind flows downward and obliquely in a first direction,
the second partial transport wind flows downward and obliquely in a second direction, and
the first direction and the second direction face each other.

### Supplement 6

The method for manufacturing a semiconductor device according to any one of supplements 1 to 4, wherein
the liquid transport wind includes first and second partial transport winds, and
the nozzle includes:
a nozzle body provided with the coating liquid supply port;
a first air supply member that supplies the first partial transport wind; and
a second air supply member that supplies the second partial transport wind,
the nozzle body is provided between the first and second air supply members,
the first partial transport wind flows downward and obliquely in a first direction,
the second partial transport wind flows downward and obliquely in a second direction, and
the first direction and the second direction face each other.

### Supplement 7

The method for manufacturing a semiconductor device according to any one of supplements 1 to 6, the method further including the steps of:
providing a primary layer containing a silane coupling agent as a constituent material on an outer periphery of the wire after the step (c) is performed; and
(d) providing a sealant over the semiconductor element, the wire, and the primary layer after the step (c) is performed.

### Supplement 8

A semiconductor device including:
a semiconductor element;
a wire electrically connected to the semiconductor element;
a primary layer provided on an outer periphery of the wire including a back surface of the wire and containing a silane coupling agent as a constituent material;
a case that houses the semiconductor element, the wire, and the primary layer inside; and
a sealant provided covering the semiconductor element, the wire, and the primary layer in the case.

While the disclosure has been shown and described in detail, the foregoing description is in all aspects illustrative and not restrictive. It is therefore understood that numerous modifications and variations can be devised.

What is claimed is:

1. A method for manufacturing a semiconductor device, the method comprising the steps of:
(a) preparing a coating target structure including a semiconductor element and a wire electrically connected to the semiconductor element;
(b) performing a coating process of supplying a coating liquid from a coating liquid supply port toward the coating target structure using a nozzle disposed above the coating target structure and having the coating liquid supply port; and
(c) drying the coating target structure after the step (b) is performed;
the coating liquid containing a silane coupling agent,
the nozzle having a transport wind generating function of generating a liquid transport wind that spirally swirls downward, and
the coating liquid being supplied to the coating target structure along a flow of the liquid transport wind.

2. The method for manufacturing a semiconductor device according to claim 1, wherein
the coating liquid is an alcohol diluent of a silane coupling agent, and
the silane coupling agent has a concentration of 1% or less.

3. The method for manufacturing a semiconductor device according to claim 1, wherein
the nozzle further includes:
a cover member provided to limit a supply region of the coating liquid below the nozzle.

4. The method for manufacturing a semiconductor device according to claim 1, wherein
the nozzle further includes:
an ultrasonic vibration function of forming the coating liquid into droplets with an ultrasonic wave of 60 to 120 kHz.

5. The method for manufacturing a semiconductor device according to claim 1, wherein
the liquid transport wind includes a combination of first partial transport wind and second partial transport wind, and
the nozzle further includes:
a first air supply port provided to supply the first partial transport wind; and
a second air supply port provided to supply the second partial transport wind,
the coating liquid supply port is provided between the first and second air supply ports,
the first partial transport wind flows downward and obliquely in a first direction,
the second partial transport wind flows downward and obliquely in a second direction, and
the first direction and the second direction face each other.

6. The method for manufacturing a semiconductor device according to claim 1, wherein
the liquid transport wind includes first partial transport wind and second partial transport wind, and
the nozzle includes:
a nozzle body provided with the coating liquid supply port;
a first air supply member that supplies the first partial transport wind; and
a second air supply member that supplies the second partial transport wind,
the nozzle body is provided between the first and second air supply members,
the first partial transport wind flows downward and obliquely in a first direction,
the second partial transport wind flows downward and obliquely in a second direction, and
the first direction and the second direction face each other.

7. The method for manufacturing a semiconductor device according to claim 1, the method further comprising the steps of:
providing a primary layer containing a silane coupling agent as a constituent material on an outer periphery of the wire after the step (c) is performed; and
(d) providing a sealant over the semiconductor element, the wire, and the primary layer after the step (c) is performed.
